(19) United States
(12) Patent Application Publication
(10) Pub. No.: US 2024/0284611 A1
(43) Pub. Date: Aug. 22, 2024

(54) SUPPORT PLATE AND DISPLAY PANEL

(71) Applicant: Wuhan China Star Optoelectronics Semiconductor Display Technology Co., Ltd., Wuhan (CN)

(72) Inventor: Lidan LI, Wuhan (CN)

(21) Appl. No.: 17/616,974

(22) PCT Filed: Oct. 28, 2021
(86) PCT No.: PCT/CN2021/126901

§ 371 Date: Apr. 30, 2024

(30) Foreign Application Priority Data
Sep. 28, 2021 (CN) 202111145200.2

(51) Int. Cl. H05K 5/02; H10K 59/80

(52) U.S. Cl. CPC H05K 5/0217; H10K 59/80

(57) ABSTRACT

A display panel includes a support plate. The support plate includes a support body. The support body comprises at least one bending area. The bending area comprises a plurality of stress relief members disposed in an array and each having a centrally symmetrical shape. Each of the stress relief members has curves in many directions. Every four adjacent stress relief members enclose a stress relief region.

### FIELD OF INVENTION

The present disclosure relates to the technical field of display, and particularly to a support plate and a display panel.

### BACKGROUND

Flexible organic light emitting diode (OLED) displays have advantages of active light emission, wide viewing angle, wide color gamut, high brightness, fast response time, low power consumption, and structural bendability and foldability, so they are more and more popular in the market. The flexible OLED displays are bendable and foldable, so they can be prepared into various forms of foldable display devices, which are convenient for carrying and storing when going out. Considering that the flexible OLED displays are relatively light and thin, metal supports are used to improve overall supportability, tensile strength, and impact resistance of the displays. However, elastic moduli of the metal supports are relatively large and are basically more than 1000 times an elastic modulus of a glue bonded to the metal supports. Therefore, during bending of the flexible OLED displays, stress is easily concentrated on the metal supports, so that the stress cannot be released in time, which causes the metal supports to break.

### SUMMARY OF INVENTION

### Technical Problems Summary of Invention

The present disclosure provides a support plate and a display panel to solve a technical problem that a metal support of a current flexible organic light emitting diode (OLED) display has a risk of fracture during bending.

### Solutions to Problems

### Technical Solutions

In order to solve the above technical problem, the present disclosure provides the following technical solutions.

The present disclosure provides a support plate comprising a support body. The support body comprises at least one bending area. The bending area comprises a plurality of stress relief members disposed in an array, and every four adjacent stress relief members enclose a stress relief region. Each of the stress relief members comprises:
a first stress relief part comprising a first physical part and a second physical part that are integrally disposed and are centrally symmetrical with respect to each other; and
a second stress relief part intersected with the first stress relief part, wherein when the second stress relief part is rotated by a preset angle around a center of symmetry of the first stress relief part, the second stress relief part overlaps with the first stress relief part.

In an embodiment, a number of the bending area is two, and bending axes of the two bending areas are parallel.

In an embodiment, the preset angle is 90 degrees, and an included angle between a centerline of the first stress relief part and the bending axis of any bending area is 45 degrees.

In an embodiment, a number of the bending area is two, and bending axes of the two bending areas intersect at a first included angle.

In an embodiment, the first included angle is equal to the preset angle.

In an embodiment, an included angle between the bending axis of one bending area and the centerline of the first stress relief part is equal to an included angle between the bending axis of the other bending area and the centerline of the first stress relief part.

In an embodiment, an intersection of the first stress relief part and the second stress relief part comprises a plurality of arc chamfers.

In an embodiment, the stress relief region is formed by four adjacent stress relief members disposed end to end in sequence.

In an embodiment, the stress relief region is a hollow structure.

In an embodiment, the stress relief region is a groove structure, and a ratio of a depth of the groove structure to a thickness of the support body is ½ to ⅘.

In an embodiment, the depth of the groove structure is 30 μm to 100 μm.

The present disclosure further provides a display panel comprising a display panel main body and the support plate of one of the above embodiments. The display panel main body comprises a light-emitting surface and a backlight surface opposite to the light-emitting surface. The support plate is disposed on the backlight surface of the display panel main body.

### BENEFICIAL EFFECTS OF INVENTION

### Beneficial Effects

In a support plate and a display panel provided by the present disclosure, a support body comprises at least one bending area. The bending area comprises a plurality of stress relief members disposed in an array, and every four adjacent stress relief members enclose a stress relief region. Each of the stress relief members comprises a first stress relief part and a second stress relief part. The first stress relief part comprises a first physical part and a second physical part that are integrally disposed and are centrally symmetrical with respect to each other. The first physical part is a fan ring comprising two concentric arcs. The second stress relief part is intersected with the first stress relief part. When the second stress relief part is rotated by a preset angle around a center of symmetry of the first stress relief part, the second stress relief part overlaps with the first stress relief part. The stress relief members are disposed in the bending area. The stress relief members have curves in many directions, which can effectively disperse stress when the support plate is bent, and intercept transfer of the stress along a bending direction. This effectively prevents the support plate from breaking due to stress concentration during bending, thereby solving the technical problem that a metal support of a current flexible OLED display has a risk of fracture during bending. Furthermore, in a case where the support plate has at least two bending areas, and the at least two bending areas have overlapping areas, structural arrangements of the stress relief members in the two bending areas are consistent, so that the two bending areas have same stress distribution and resilience during bending. This reduces bending stress in the bending areas and makes the bending areas have a consistent rigidity.

### BRIEF DESCRIPTION OF DRAWINGS

### Description of Drawings

In order to more clearly illustrate technical solutions in embodiments of the present disclosure or the prior art, a brief description of accompanying drawings used in the embodiments or the prior art will be given below. The accompanying drawings in the following description are merely some embodiments of the present disclosure. For those skilled in the art, other drawings may be obtained from these accompanying drawings without creative labor.

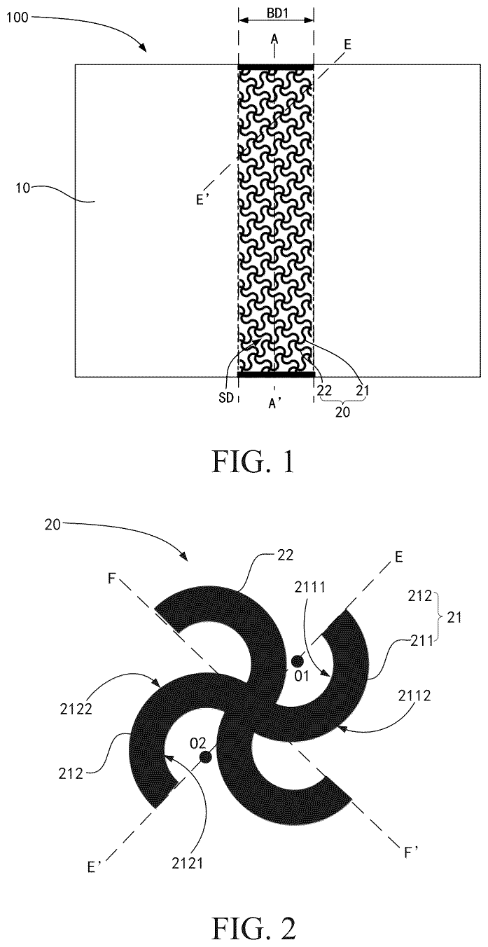

FIG. 1 is a schematic top view of a type of support plate according to an embodiment of the present disclosure.

FIG. 2 is a detailed structural diagram of a type of stress relief member according to an embodiment of the present disclosure.

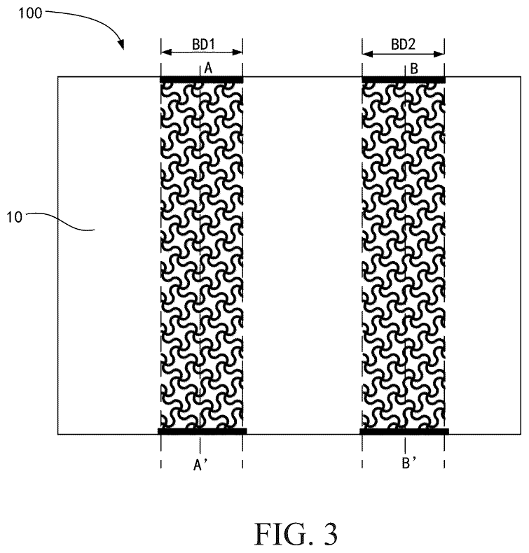

FIG. 3 is a schematic top view of another type of support plate according to an embodiment of the present disclosure.

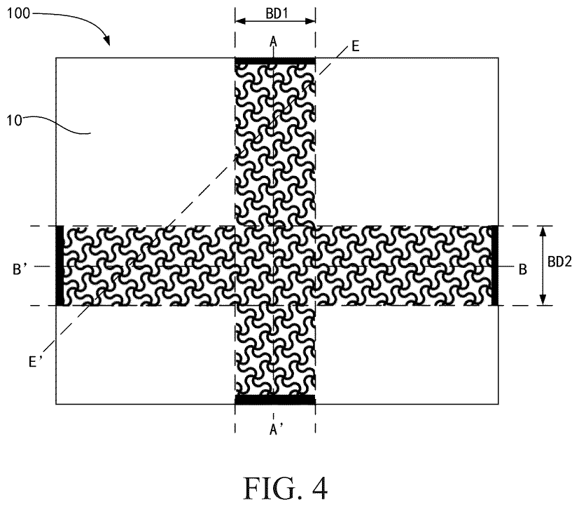

FIG. 4 is a schematic top view of still another type of support plate according to an embodiment of the present disclosure.

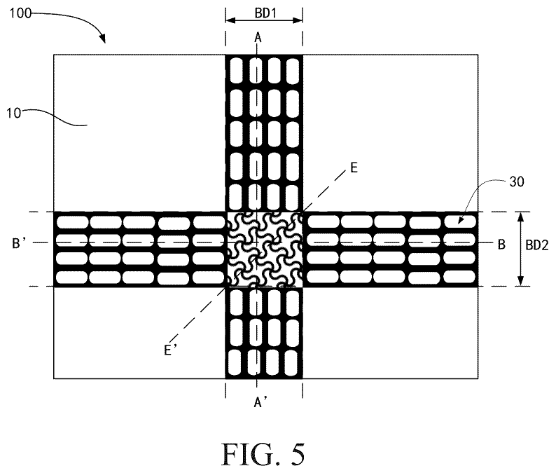

FIG. 5 is a schematic top view of yet another type of support plate according to an embodiment of the present disclosure.

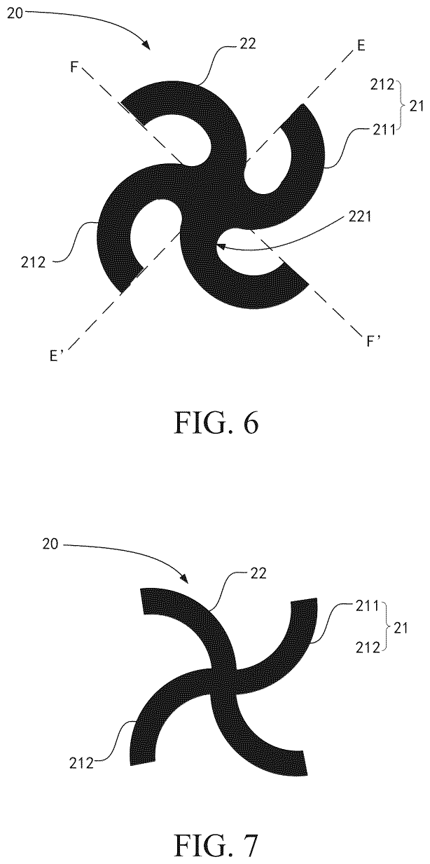

FIG. 6 is a detailed structural diagram of another type of stress relief member according to an embodiment of the present disclosure.

FIG. 7 is a detailed structural diagram of still another type of stress relief member according to an embodiment of the present disclosure.

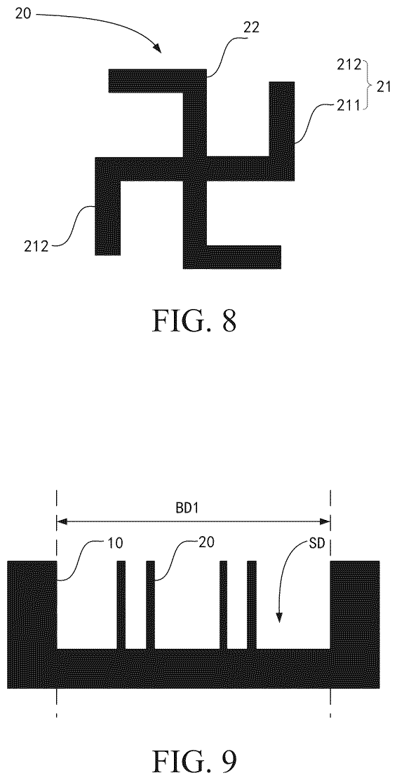

FIG. 8 is a detailed structural diagram of yet another type of stress relief member according to an embodiment of the present disclosure.

FIG. 9 is a schematic partial cross-sectional view of a support plate according to an embodiment of the present disclosure.

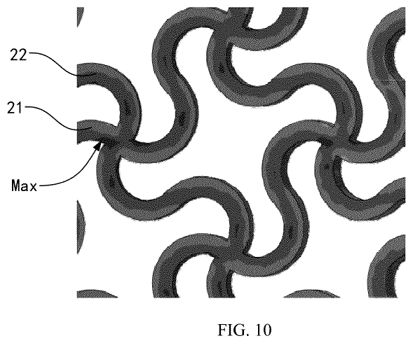

FIG. 10 is a schematic diagram of a simulated stress distribution of a support plate according to an embodiment of the present disclosure.

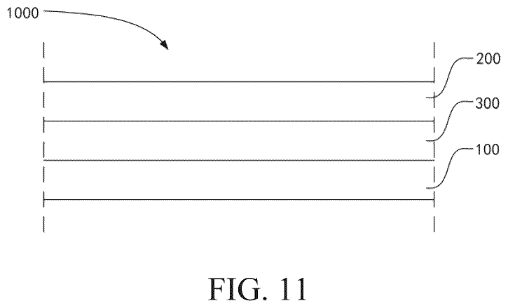

FIG. 11 is a schematic cross-sectional view of a display panel according to an embodiment of the present disclosure.

### EMBODIMENTS OF INVENTION

### Embodiments of Invention

The following description of various embodiments of the present disclosure with reference to the accompanying drawings is used to illustrate specific embodiments that can be practiced. Directional terms mentioned in the present disclosure, such as “above”, “below”, “front”, “back”, “left”, “right”, “inside”, “outside”, “side”, are merely used to indicate the direction of the accompanying drawings. Therefore, the directional terms are used for illustrating and understanding the present disclosure rather than limiting the present disclosure. In the figures, elements with similar structure are indicated by the same reference numerals. In the accompanying drawings, thicknesses of some layers and regions are exaggerated for clear understanding and ease of description. That is, a size and thickness of each component shown in the accompanying drawings are arbitrarily shown, but the present application is not limited thereto.

Please refer to FIG. 1 and FIG. 2. FIG. 1 is a schematic top view of a type of support plate according to an embodiment of the present disclosure. FIG. 2 is a detailed structural diagram of a type of stress relief member according to an embodiment of the present disclosure. A support plate 100 comprises a support body 10. The support body 10 comprises at least one bending area (e.g., a first bending area BD1 shown in FIG. 1). The bending area comprises a plurality of stress relief members 20 disposed in an array. Every four adjacent stress relief members 20 enclose a stress relief region SD. The stress relief regions SD have a same shape and size. Optionally, the stress relief regions SD are hollow structures. The stress relief regions SD can intercept transfer of bending stress along a bending direction when the support plate 100 is bent, which effectively prevents the support plate 100 from breaking due to stress concentration during bending.

A structure of the bending area will be described in detail below by taking the supporting body 10 comprising one bending area as an example. For convenience of description, the bending area is named the first bending area BD1.

Optionally, the stress relief members 20 and the support body 10 are integrally disposed. That is, the stress relief members 20 are formed by etching the support body 10 of the support plate 100 in the first bending area BD1. Regions of the support body 10 that are etched away are the stress relief regions SD. In this embodiment, the stress relief regions SD are hollow structures. That is, parts of the support body 10 in the first bending area BD1 are etched into through holes as the stress relief regions SD. Remaining parts of the support body 10 that have not been etched away in the first bending area BD1 are the stress relief members 20. The support body 10 may be made of metals such as stainless steel, structural steel, titanium alloy, etc., but is not limited thereto. The support body 10 may also be made of polymer materials or the like.

Each of the stress relief members 20 comprises a first stress relief part 21 and a second stress relief part 22. The first stress relief part 21 comprises a first physical part 211 and a second physical part 212 that are integrally disposed. The first physical part 211 and the second physical part 212 are centrally symmetrical with respect to each other. Therefore, the first stress relief part 21 has a centrally symmetrical shape. That is, the first physical part 211 and the second physical part 212 are centrally symmetrical with respect to a center of symmetry of the first stress relief part 21. More specifically, when the first physical part 211 is rotated by 180 degrees around the center of symmetry of the first stress relief part 21, the first physical part 211 overlaps with the second physical part 212. The center of symmetry of the first stress relief part 21 is located at a midpoint of a boundary between the first physical part 211 and the second physical part 212.

Optionally, each of the first physical part 211 and the second physical part 212 has an axisymmetric shape. Specifically, the first physical part 211 is a fan ring comprising two concentric arcs. The two concentric arcs of the first physical part 211 are a first arc 2111 and a second arc 2112. Optionally, the first arc 2111 and the second arc 2112 are two concentric semicircles, so that the fan ring comprising the first arc 2111 and the second arc 2112 is a semicircular ring. The semicircular ring is the first physical part 211. The first arc 2111 and the second arc 2112 have a same first center O1. A radius of the second arc 2112 is greater than a radius of the first arc 2111.

Correspondingly, the second physical part 212 is also a fan ring comprising two concentric arcs. The two concentric arcs of the second physical part 212 are a third arc 2121 and a fourth arc 2122. Because the first physical part 211 and the second physical part 212 are centrally symmetrical with respect to each other, optionally, the third arc 2121 and the fourth arc 2122 are also two concentric semicircles. Therefore, the fan ring comprising the third arc 2121 and the fourth arc 2122 is a semicircular ring, and the semicircular ring is the second physical part 212. The third arc 2121 and the fourth arc 2122 have a same second center O2. A radius of the fourth arc 2122 is greater than a radius of the third arc 2121. The first arc 2111 is circumscribed to the fourth arc 2122. The second circular arc 2112 is circumscribed to the third circular arc 2121.

The second stress relief part 22 is intersected with the first stress relief part 21. When the second stress relief part 22 is rotated by a preset angle around the center of symmetry of the first stress relief part 21, the second stress relief part 22 overlaps with the first stress relief part 21. That is, the second stress relief part 22 has a same structure as the first stress relief part 21. For example, each of the first physical part 211 and the second physical part 212 of the first stress relief part 21 has an axisymmetric shape, and correspondingly, two physical parts of the second stress relief part 22 also have an axisymmetric shape. This ensures the stress relief region SD enclosed by the stress relief members 20 is balanced in all directions, thereby further avoiding the stress concentration when the support plate 100 is bent. Furthermore, for a specific structure of the second stress relief part 22, reference may be made to the above description of the first stress relief part 21, which will not be described in detail herein.

Moreover, because the first stress relief part 21 has a centrally symmetrical shape, the second stress relief part 22 also has a centrally symmetrical shape. Therefore, the stress relief member 20 has a centrally symmetrical shape as a whole. The stress relief member 20 has curves in many directions as a whole, which can effectively disperse stress when the support plate 100 is bent, and intercept transfer of the stress along the bending direction. This effectively prevents the support plate 100 from breaking during bending.

It should be noted that the preset angle may refer to an included angle between the first stress relief part 21 and the second stress relief part 22. The included angle between the first stress relief part 21 and the second stress relief part 22 refers to an included angle between a centerline E-E′ of the first stress relief part 21 and a centerline F-F′ of the second stress relief part 22. The centerline E-E′ of the first stress relief part 21 refers to a straight line connecting an end of the first physical part 211 away from the second physical part 212, the center of symmetry of the first stress relief part 21, and an end of the second physical part 212 away from the first physical part 211. A definition of the centerline F-F′ of the second stress relief part 22 is same as the above definition of the centerline E-E′ of the first stress relief part 21. A point where the centerline E-E′ of the first stress relief part 21 intersects with the centerline F-F′ of the second stress relief part 22 is the center of symmetry of the first stress relief part 21. Optionally, the preset angle is 90 degrees. Setting the preset angle to 90 degrees can make the stress relief regions SD enclosed by the stress relief members 20 all have a same area, which can evenly disperse bending stress in the first bending area BD1, thereby better avoiding stress concentration in the first bending area BD1.

Furthermore, in order to enable the stress relief members 20 to not only reduce the bending stress in the first bending area BD1, but also to take into account resilience of the support plate 100, the stress relief members 20 may be arranged at a certain angle with respect to a bending axis A-A′ of the first bending area BD1. Optionally, the stress relief members 20 are arranged at 45 degrees with respect to the bending axis A-A′ of the first bending area BD1. That is, the centerline E-E′ of the first stress relief part 21 and the bending axis A-A′ of the first bending area BD1 form an angle of 45 degrees. The centerline F-F′ of the second stress relief part 22 and the centerline E-E′ of the first stress relief part 21 form an angle of 90 degrees. Therefore, the centerline F-F′ of the second stress relief part 22 and the bending axis A-A′ of the first bending area BD1 also form an angle of 45 degrees. Therefore, when the support plate 100 is bent along the bending axis AA′ of the first bending area BD1, the stress relief members 20 disposed in the first bending area BD1 can effectively reduce the bending stress and prevent the support plate 100 from breaking due to stress concentration during bending. Furthermore, because an included angle between the centerline E-E′ of the first stress relief part 21 and the bending axis A-A′ of the first bending area BD1 is equal to an included angle between the centerline F-F′ of the second stress relief part 22 and the bending axis A-A′ of the first bending area BD1, the first stress relief part 21 and the second stress relief part 22 jointly bear the stress, so that the support plate 100 has good resilience in the first bending area BD1. Therefore, structure and material properties of the stress relief members 20 can be fully utilized. However, the present application is not limited to this, and the stress relief members 20 may also be arranged at other angles with respect to the bending axis A-A′ of the first bending area BD1.

The stress relief members 20 are arranged in an array along a direction at an angle of 45 degrees with respect to the bending axis A-A′ of the first bending area BD1. The stress release members 20 are connected end to end, and every four adjacent stress relief members 20 enclose one stress relief region SD. The stress relief members 20 being connected end to end means that in two adjacent stress relief members 20, two adjacent first stress relief parts 21 are connected, and two adjacent second stress relief parts 22 are connected. More specifically, taking two first stress relief parts 21 as an example, an end of the first physical part 211 of one first stress relief part 21 is connected to an end of the second physical part 212 of the adjacent first stress relief part 21.

In this embodiment, the support body 10 comprises the bending area BD1, and the bending area BD1 comprises the stress relief members 20. The stress relief members 20 have curves in all directions as a whole, which can effectively disperse stress when the support plate 100 is bent, and thus effectively prevents the support plate 100 from breaking during bending. Furthermore, the stress relief members 20 are arranged at an angle of 45 degrees with respect to the bending axis A-A′ of the first bending area BD1, and the first stress relief part 21 and the second stress relief part 22 of each stress relief member 20 form an angle of 90, so that the first stress relief part 21 and the second stress relief part 22 jointly bear the stress, so as to ensure that the support plate 100 also has good resilience in the first bending area BD1, and the structure and material properties of the stress relief members 20 are fully utilized.

Please refer to FIG. 3. FIG. 3 is a schematic top view of another type of support plate according to an embodiment of the present disclosure. This embodiment differs from the above embodiment in that a number of bending areas of a support body 10 of a support plate 100 is two, and bending axes of the two bending areas are parallel. Specifically, the two bending areas are a first bending area BD1 and a second bending area BD2. A bending axis A-A′ of the first bending area BD1 is parallel to a bending axis B-B′ of the second bending area BD2. The first bending area BD1 is provided with a plurality of stress relief members 20 arranged in an array. The stress relief members 20 are arranged at an angle of 45 degrees with respect to the bending axis A-A′ of the first bending area BD1, and the first stress relief part 21 and the second stress relief part 22 of each stress relief member 20 form an angle of 90, so that an included angle between the first stress relief part 21 and the bending axis A-A′ of the first bending area BD1 is equal to an included angle between the second stress relief part 22 and the bending axis A-A′ of the first bending area BD1. Therefore, the stress relief members 20 can effectively reduce bending stress, and thus prevent the support plate 100 from breaking due to stress concentration when the first bending area BD1 is bent. The stress relief members 20 can also enable the support plate 100 to have good resilience in the first bending area BD1. A structure of the second bending area BD2 is same as a structure of the first bending area BD1, and a bending direction of the second bending area BD2 is same as a bending direction of the first bending area BD1, so that the second bending area BD2 has same effects as the first bending area BD1. For other details, reference may be made to the above embodiment, which will not be described herein.

Please refer to FIG. 4. FIG. 4 is a schematic top view of still another type of support plate according to an embodiment of the present disclosure. This embodiment differs from the above embodiments in that a number of bending areas of a support body 10 of a support plate 100 is two, and bending axes of the two bending areas intersect at a first included angle. Specifically, the two bending areas are a first bending area BD1 and a second bending area BD2. A bending axis A-A′ of the first bending area BD1 and a bending axis B-B′ of the second bending area BD2 intersect at the first included angle. Therefore, a bending direction of the first bending area BD1 is different from a bending direction of the second bending area BD2, and the first bending area BD1 and the second bending area BD2 have an overlapping area. The overlapping area needs to meet bending requirements in different directions.

Optionally, the first included angle is equal to the preset angle. That is, an included angle between the bending axis A-A′ of the first bending area BD1 and the bending axis B-B′ of the second bending area BD2 is equal to an included angle between the centerline E-E′ of the first stress relief part 21 and the centerline F-F′ of the second stress relief part 22. This can ensure that whether the support plate 100 is bent along the bending axis A-A′ of the first bending area BDlor along the bending axis B-B′ of the second bending area BD2, the stress relief members 20 in the first bending area BD1 and the stress relief members 20 in the second bending area BD2 all bear stress.

Furthermore, an included angle between the bending axis of one bending area and the centerline E-E′ of the first stress relief part 21is equal to an included angle between the bending axis of the other bending area and the centerline E-E′ of the first stress relief part 21. That is, an included angle between the bending axis A-A′ of the first bending area BD1 and the centerline E-E′ of the first stress relief part 21 is equal to an included angle between the bending axis B-B′ of the second bending area BD2 and the centerline E-E′ of the first stress relief part 21. An included angle between the centerline E-E′ of the first stress relief part 21 and the centerline F-F′ of the second stress relief part 22 is equal to an included angle between the bending axis A-A′ of the first bending area BD1 and the bending axis B-B′ of the second bending area BD2. Therefore, an included angle between the bending axis A-A′ of the first bending area BD1 and the centerline F-F′ of the second stress relief part 22 is equal to an included angle between the bending axis B-B′ of the second bending area BD2 and the centerline F-F′ of the second stress relief part 22. Accordingly, the stress relief members 20 in the first bending area BD1 and the second bending area BD2 have a same arrangement, reduce bending stress in the bending areas, and have a same rigidity. Therefore, stress distribution and resilience of the support plate 100 when the support plate 100 is bent along the bending axis AA′ of the first bending area BD1 are same as stress distribution and resilience of the support plate 100 when the support plate 100 is bent along the bending axis B-B′ of the second bending area BD2. The support plate 100 has a spring-like structure in different bending directions and has good ductility.

Optionally, taking the first included angle of 90 degrees as an example for illustration, the included angle between the bending axis A-A′ of the first bending area BD1 and the bending axis B-B′ of the second bending area BD2 is 90 degrees, and the included angle between the first stress relief part 21 and the second stress relief part 22 is also 90 degrees. The stress relief members 20 are arranged in the array along the direction at the angle of 45 degrees with respect to the bending axis A-A′ of the first bending area BD1, or along a direction at an angle of 45 degrees with respect to the bending axis B-B′ of the second bending area BD2. The included angle between the first stress relief part 21 and the bending axis A-A′ of the first bending area BD1 and an included angle between the first stress relief part 21 and the bending axis B-B′ of the second bending area BD2 are 45 degrees. The included angle between the second stress relief part 22 and the bending axis A-A′ of the first bending area BD1 and an included angle between the second stress relief part 22 and the bending axis B-B′ of the second bending area BD2 are 45 degrees. Therefore, when the support member is bent, the first stress relief part 21 and the second stress relief part 22 bear same stress. This avoids a situation where the one who bears larger stress is easily damaged, and the one who bears smaller stress cannot exert its structural performance. Accordingly, the stress distribution and the resilience of the support plate 100 when the support plate 100 is bent along the bending axis AA′ of the first bending area BD1 are same as the stress distribution and the resilience of the support plate 100 when the support plate 100 is bent along the bending axis B-B′ of the second bending area BD2.

It should be noted that the present application is not limited to that the bending axes of the two bending areas have a same included angle with the centerline E-E′ of the first stress relief part 21. For example, the centerline E-E′ of the first stress relief part 21 of the present application may also be parallel to the bending axis A-A′ of the first bending area BD1 or the bending axis B-B′ of the second bending area BD2. Take as an example that the centerline E-E′ of the first stress relief part 21 is parallel to the bending axis A-A′ of the first bending area BD1, when the support plate 100 is bent along the bending axis A-A′ of the first bending area BD1, the first stress relief part 21 hardly bears stress, and the second stress relief part 22 bears the stress. When the support plate 100 is bent along the bending axis B-B′ of the second bending area BD2, the second stress relief part 22 hardly bears stress, and the first stress relief part 21 bears the stress. In this case, the stress relief members 20 can also play a role in reducing the bending stress in the bending areas. For other details, reference may be made to the above embodiments, which will not be described herein.

Please refer to FIG. 5. FIG. 5 is a schematic top view of yet another type of support plate according to an embodiment of the present disclosure. This embodiment differs from the above embodiments in that a bending axis A-A′ of a first bending area BD1 and a bending axis B-B′ of a second bending area BD2 intersect at a first angle. A bending direction of the first bending area BD1 is different from a bending direction of the second bending area BD2. The first bending area BD1 and the second bending area BD2 have an overlapping area. The overlapping area is provided with a plurality of stress relief members 20. Non-overlapping areas of the first bending area BD1 and the second bending area BD2 may be provided with other hollow structures, such as elongated hollow structures 30 shown in FIG. 5. A long axis of one elongated hollow structure 30 is parallel to a bending axis of one corresponding bending area. A structural arrangement of the stress relief members 20 in the overlapping area in FIG. 5 of this embodiment is same as a structural arrangement of the stress relief members 20 in the overlapping area of the first bending area BD1 and the second bending area BD2 in FIG. 4. This can also avoid a risk of breakage when the support plate is bent in multiple directions. For other details, reference may be made to the above embodiments, which will not be described herein.

Please refer to FIG. 6. FIG. 6 is a detailed structural diagram of another type of stress relief member according to an embodiment of the present disclosure. This embodiment differs from the above embodiments in that an intersection of the first stress relief part 21 and the second stress relief part 22 of each stress relief member 20 comprises a plurality of arc chamfers 221. Considering bending stress and resilience of the stress relief member 20, it is necessary to provide the stress relief member 20 with a smaller size. Furthermore, the stress relief member 20 has curves in all directions. Therefore, the intersection of the first stress relief part 21 and the second stress relief part 22 has a plurality of narrow sharp corners. In terms of a manufacturing process, high process accuracy is required to realize the narrow sharp corners, which will inevitably affect yield and increase cost. Compared with the narrow sharp corners, the arc chamfers 221 are easier to realize in terms of a manufacturing process, and its process accuracy is easier to achieve. For other details, reference may be made to the above embodiments, which will not be described herein.

Please refer to FIG. 7. FIG. 7 is a detailed structural diagram of still another type of stress relief member according to an embodiment of the present disclosure. This embodiment differs from the above embodiments in that one stress relief member 20 comprises a first stress relief part 21 and a second stress relief part 22, the first stress relief part 21 comprises a first physical part 211 and a second physical part 212, and the first physical part 211 and the second physical part 212 are each a fan ring composed of two concentric one-third circles. The fan ring is a one-third ring. The one-third ring herein refers to a one-third part of a ring. The stress relief members 20 of this embodiment can also effectively prevent a support plate from breaking due to stress concentration during bending. For other details, reference may be made to the above embodiments, which will not be described herein.

Please refer to FIG. 8. FIG. 8 is a detailed structural diagram of yet another type of stress relief member according to an embodiment of the present disclosure. This embodiment differs from the above embodiments in that one stress relief member 20 comprises a first stress relief part 21 and a second stress relief part 22, the first stress relief part 21 comprises a first physical part 211 and a second physical part 212, and each of the first physical part 211 and the second physical part 212 is formed by two bars intersecting at a certain angle. Preferably, the certain angle is 90 degrees, and the two intersecting bars are mirror-symmetrical to each other. The stress relief members 20 of this embodiment can also effectively prevent a support plate from breaking due to stress concentration during bending. For other details, reference may be made to the above embodiments, which will not be described herein.

Please refer to FIG. 9. FIG. 9 is a schematic partial cross-sectional view of a support plate according to an embodiment of the present disclosure. This embodiment differs from the above embodiments in that each stress relief region SD is a groove structure, and a ratio of a depth of the groove structure to a thickness of the support body 10 is ½ to ⅘. Optionally, the depth of the groove structure is 30 μm to 100 μm. Taking the first bending area BD1 as an example, setting each stress relief region SD in the first bending area BD1 as the groove structure with a certain depth can also disperse the bending stress in the first bending area BD1, and prevent the support plate 100 from breaking due to stress concentration in the first bending area BD1. Furthermore, the groove structure allows the first bending area BD1 to retain more support material, which improves support performance of the support plate 100 in the first bending area BD1, so that the stress and resilience of the first bending area BD1 can be better considered. For other details, reference may be made to the above embodiments, which will not be described herein.

Furthermore, in order to verify reliability of the support plate of the present application, the inventor of the present application took the support plate 100 in one of the above embodiments as an example to simulate stress distribution of the support plate 100 when the support plate 100 was bent. Specifically, please refer to FIG. 10. FIG. 10 is a schematic diagram of a simulated stress distribution of a support plate according to an embodiment of the present disclosure. Taking the support plate 100 made of stainless steel as an example for simulation. The first bending area BD1 of the support plate 100 is bent into a U-shape with a bending radius of 5 mm. According to the schematic diagram of the simulated stress distribution, distribution of bending stress in the support plate 100 in the first bending area BD1 of the present application is relatively uniform. Bending stress at the intersection of the first stress relief part 21 and the second stress relief part 22 is the maximum. The maximum stress Max is 940 MPa, which is much less than a yield stress of stainless steel (above 1600 MPa), so that the support plate 100 basically has no risk of breaking during bending. Furthermore, the stress relief members 20 in the first bending area BD1 have the same structure as the stress relief members 20 in the second bending area BD2. When the first bending area BD1 is rotated by 90 degrees around its center of symmetry, the stress relief members 20 in the first bending area BD1 completely overlap with the stress relief members 20 in the second bending area BD2. Therefore, when the support plate 100 is bent along the bending axis B-B′ of the second bending area BD2, bending stress distribution of the second bending area BD2 is same as the bending stress distribution of the first bending area BD1.

The present disclosure further provides a display panel. Please refer to FIG. 11. FIG. 11 is a schematic cross-sectional view of a display panel according to an embodiment of the present disclosure. The display panel 1000 comprises a display panel main body 200 and the support plate 100 of one of the above embodiments. In this embodiment, the support plate 100 is taken as an example for description. The display panel main body 200 comprises a light-emitting surface and a backlight surface opposite to the light-emitting surface. The support plate 100 is disposed on the backlight surface of the display panel main body 200.

Optionally, the display panel 1000 may be an OLED display panel, a QLED display panel, a QD-OLED display panel, a liquid crystal display panel, or the like. Taking the display panel 1000 as an OLED display panel as an example, the display panel main body 200 may comprise a substrate, and a driving circuit layer, a light-emitting function layer, an encapsulation layer, and the like, which are sequentially disposed on the substrate.

Optionally, a back plate 300 may be further disposed between the support plate 100 and the display panel main body 200 to further improve structural reinforcement and heat dissipation of the display panel main body 200. The back plate 300 may be fixed on the backlight surface of the display panel main body 200 by pressure sensitive adhesive (PSA) or the like. The support plate 100 is fixed on a side of the back plate 300 away from the display panel main body 200 by optically clear adhesive (OCA). The back plate 300 may be one or a combination of two or more of foam, graphite layer, copper foil, and the like.

According to the above embodiments, the following can be known.

The present disclosure provides a support plate and a display panel. A support body of the support plate comprises at least one bending area. The bending area comprises a plurality of stress relief members disposed in an array, and every four adjacent stress relief members enclose a stress relief region. Each of the stress relief members comprises a first stress relief part and a second stress relief part. The first stress relief part comprises a first physical part and a second physical part that are integrally disposed and are centrally symmetrical with respect to each other. The first physical part is a fan ring comprising two concentric arcs. The second stress relief part is intersected with the first stress relief part. When the second stress relief part is rotated by a preset angle around a center of symmetry of the first stress relief part, the second stress relief part overlaps with the first stress relief part. The stress relief members are disposed in the bending area. The stress relief members have curves in many directions, which can effectively disperse stress when the support plate is bent, and intercept transfer of the stress along a bending direction. This effectively prevents the support plate from breaking due to stress concentration during bending, thereby solving the technical problem that a metal support of a current flexible OLED display has a risk of fracture during bending.

In the above embodiments, the description of each embodiment has its own emphasis. For parts not detailed in one embodiment, reference may be made to the related descriptions in other embodiments.

The embodiments of the present disclosure are described in detail above. The present disclosure uses specific examples to describe principles and embodiments of the present application. The above description of the embodiments is only for helping to understand the technical solutions of the present disclosure and its core ideas. It should be understood by those skilled in the art that they can modify the technical solutions recited in the foregoing embodiments, or replace some of technical features in the foregoing embodiments with equivalents. These modifications or replacements do not cause essence of corresponding technical solutions to depart from the scope of the technical solutions of the embodiments of the present disclosure.

What is claimed is:

1. A support plate, comprising a support body comprising at least one bending area, wherein the bending area comprises a plurality of stress relief members disposed in an array, every four adjacent stress relief members enclose a stress relief region, and each of the stress relief members comprises:
a first stress relief part comprising a first physical part and a second physical part that are integrally disposed and are centrally symmetrical with respect to each other; and
a second stress relief part intersected with the first stress relief part, wherein when the second stress relief part is rotated by a preset angle around a center of symmetry of the first stress relief part, the second stress relief part overlaps with the first stress relief part.

2. The support plate according to claim 1, wherein a number of the bending area is two, and bending axes of the two bending areas are parallel.

3. The support plate according to claim 2, wherein the preset angle is 90 degrees, and an included angle between a centerline of the first stress relief part and the bending axis of any bending areas is 45 degrees.

4. The support plate according to claim 1, wherein a number of the bending area is two, and bending axes of the two bending areas intersect at a first included angle.

5. The support plate according to claim 4, wherein the first included angle is equal to the preset angle.

6. The support plate according to claim 5, wherein an included angle between the bending axis of one bending area and the centerline of the first stress relief part is equal to an included angle between the bending axis of the other bending area and the centerline of the first stress relief part.

7. The support plate according to claim 1, wherein the first physical part is a fan ring comprising two concentric arcs.

8. The support plate according to claim 1, wherein an intersection of the first stress relief part and the second stress relief part comprises a plurality of arc chamfers.

9. The support plate according to claim 1, wherein the stress relief region is formed by four adjacent stress relief members disposed end to end in sequence.

10. The support plate according to claim 9, wherein the stress relief region is a hollow structure.

11. The support plate according to claim 9, wherein the stress relief region is a groove structure, and a ratio of a depth of the groove structure to a thickness of the support body is ½ to ⅘.

12. The support plate according to claim 11, wherein the depth of the groove structure is 30 μm to 100 μm.

13. A display panel, comprising:
a display panel main body comprising a light-emitting surface and a backlight surface opposite to the light-emitting surface; and
a support plate disposed on the backlight surface of the display panel main body and comprising a support body comprising at least one bending area, wherein the bending area comprises a plurality of stress relief members disposed in an array, every four adjacent stress relief members enclose a stress relief region, and each of the stress relief members comprises:
a first stress relief part comprising a first physical part and a second physical part that are integrally disposed and are centrally symmetrical with respect to each other; and
a second stress relief part intersected with the first stress relief part, wherein when the second stress relief part is rotated by a preset angle around a center of symmetry of the first stress relief part, the second stress relief part overlaps with the first stress relief part.

14. The display panel according to claim 13, wherein a number of the bending area is two, and bending axes of the two bending areas intersect at a first included angle.

15. The display panel according to claim 14, wherein the first included angle is equal to the preset angle.

16. The display panel according to claim 15, wherein an included angle between the bending axis of one bending area and the centerline of the first stress relief part is equal to an included angle between the bending axis of the other bending area and the centerline of the first stress relief part.

17. The display panel according to claim 13, wherein the first physical part is a fan ring comprising two concentric arcs.

18. The display panel according to claim 13, wherein an intersection of the first stress relief part and the second stress relief part comprises a plurality of arc chamfers.

19. The display panel according to claim 13, wherein the stress relief region is formed by four adjacent stress relief members disposed end to end in sequence.

20. The display panel according to claim 19, wherein the stress relief region is a hollow structure.
